(19) United States
(12) Patent Application Publication
(10) Pub. No.: US 2015/0009646 A1
(43) Pub. Date: Jan. 8, 2015

(54) DISPLAY APPARATUS

(71) Applicant: Samsung Display Co., Ltd., Yongin-city (KR)

(72) Inventor: Byung-Uk HAN, Cheonan-si (KR)

(21) Appl. No.: 14/319,891

(22) Filed: Jun. 30, 2014

(30) Foreign Application Priority Data
Jul. 4, 2013 (KR) 10-2013-0078151

(51) Int. Cl. H05K 5/02; H05K 5/00

(52) U.S. Cl. CPC H05K 5/0217; H05K 5/0017
USPC 361/784

(57) ABSTRACT

A display apparatus includes a first substrate having a sealing area and a peripheral area surrounding the sealing area, a pixel disposed in the sealing area, a second substrate opposite to the first substrate, a sealing member disposed at a boundary of the sealing area and the peripheral area, and a plurality of shock absorbers. The pixel is disposed on the first substrate. The sealing member encapsulates the pixel, and includes at least one or more sealant, and forms a closed loop. The shock absorbers are arranged toward to the peripheral area from one side of the closed loop.

### CROSS REFERENCE TO RELATED APPLICATION

This application claims priority under 35 USC §119 to Korean Patent Application No. 10-2013-0078151, filed on Jul. 4, 2013, which is hereby incorporated by reference for all purposes as if fully set forth herein.

### BACKGROUND

1. Field

Exemplary embodiments of the present invention relate generally to a display apparatus. More particularly, exemplary embodiments of the inventive concept relate to a display apparatus having improved durability.

2. Discussion of the Background

A display apparatus has been widely used as a display unit of a television receiver, a computer monitor, and various other electronic devices. In particular, a flat display apparatus has recently been widely used due to a slim thickness, low power consumption and light weight. Commercial embodiments of flat display apparatuses include, for example, liquid crystal displays (LCDs), plasma display panels (PDPs), field emission displays (FEDs), and organic light emitting displays (OLEDs).

A display device of the display apparatus is sensitive to moisture and gas. Thus, the display device should be isolated from an external environment including the moisture and gas, in order to improve the lifespan of the display device. In order to isolate the display device, an encapsulation process is conducted. The encapsulation process is conducted by using a sealing member. A frit is one of the sealing members. The frit is widely used as the sealing member because the frit has high adhesiveness and high moisture-proof characteristics. In addition, the frit provides advanced encapsulating quality while maintaining a desirable thin profile.

However, the frit is fragile to excessive stress, because the frit is based on a brittle glass. In particular, frequent impacts to a display panel of the display apparatus occur during a process of manufacturing a wide-screen display apparatus. Stresses caused by the impact are typically concentrated on a sealing portion. As a result, breakage of the sealing member occurs frequently, thereby reducing the productivity of display apparatus manufacturing. The concentration of the stress occurs frequently at a corner region of a closed loop that is formed by the sealing member. Therefore, defects of the display apparatus are increased and a productivity yield is reduced. Thus, the cost to produce a display apparatus is increased.

### SUMMARY

Exemplary embodiments provide a display apparatus having high durability and high productivity. 1

Additional features of the invention will be set forth in the description which follows, and in part will be apparent from the description, or may be learned by practice of the invention.

According to some exemplary embodiments of the present invention, a display apparatus includes a first substrate, a second substrate, a sealing member and a plurality of shock absorbers. The first substrate has a sealing area and a peripheral area surrounding the sealing area. The first substrate further includes a pixel area disposed in the sealing area. The second substrate is opposite to the first substrate. The sealing member is disposed at a boundary of the sealing area and the peripheral area. Pixel elements are disposed on the first substrate in the pixel area. The sealing member encapsulates the pixel elements, and includes at least one sealant, and forms a closed loop. The shock absorbers are arranged toward to the peripheral area from one side of the closed loop.

The display apparatus according to an exemplary embodiment of the present invention may include a plurality of shock absorbers and/or shock outlets. The shock absorbers and the shock outlets absorb a shockwave caused by an external impact and exhaust the shockwave, so that the shock absorbers and the shock outlets may prevent the sealing member from a breaking caused by the stress concentrated on the corner region of the closed loop. Thus, the durability and the productivity of the display apparatus are improved.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a planar view illustrating a display apparatus according to an exemplary embodiment of the present invention.

FIG. 2 is an enlarged perspective view illustrating shock absorbers of the display apparatus of FIG. 1.

FIG. 3 is a cross sectional view taken along a line A-B of FIG. 1.

FIG. 4 is a cross sectional view illustrating a display apparatus according to another exemplary embodiment of the present invention.

FIG. 5 is a cross sectional view illustrating a display apparatus according to another exemplary embodiment of the present invention.

FIG. 6A is a planar view illustrating a display apparatus according to another exemplary embodiment of the present invention.

FIG. 6B is a planar view illustrating a display apparatus according to another exemplary embodiment of the present invention.

FIG. 7A is a planar view illustrating a display apparatus according to another exemplary embodiment of the present invention.

FIG. 7B is a planar view illustrating a display apparatus according to another exemplary embodiment of the present invention.

FIG. 8 is a planar view illustrating a display apparatus according to another exemplary embodiment of the present invention.

FIG. 9 is a planar view illustrating a display apparatus according to further still another exemplary embodiment of the present invention.

### DETAILED DESCRIPTION

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular exemplary embodiments only and is not intended to be limiting of the present inventive concept. As used herein, the singular forms “a,” “an” and “the” are intended to include the plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

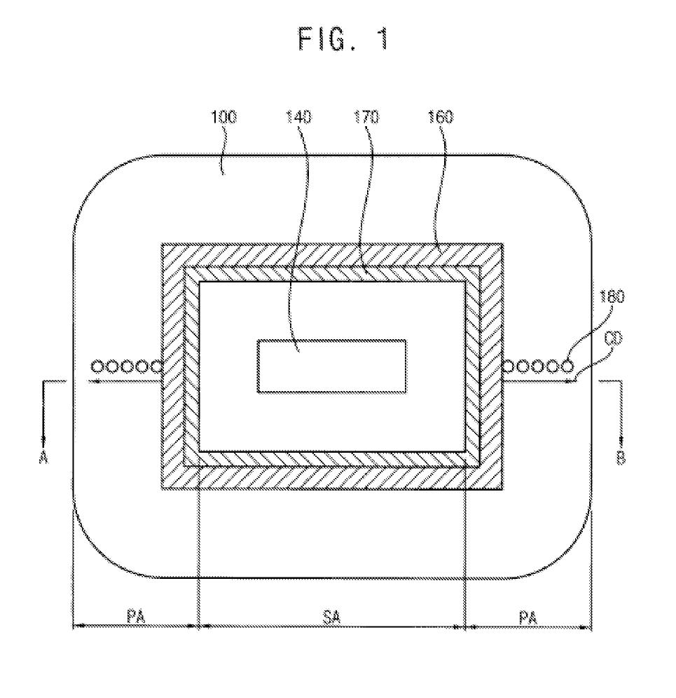

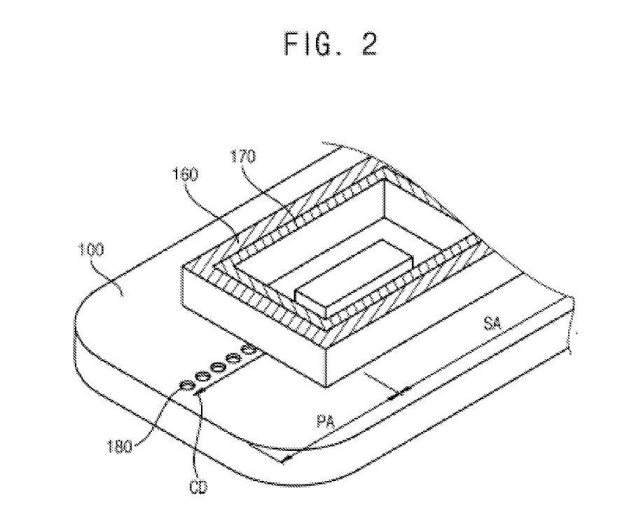

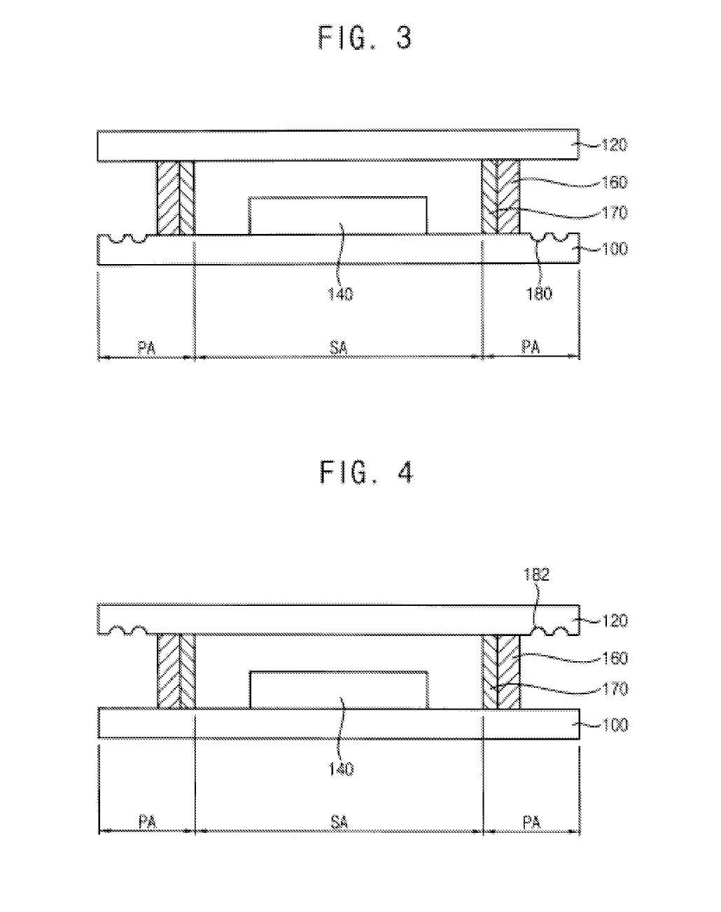

FIG. 1 is a planar view illustrating a display apparatus according to an exemplary embodiment of the present invention. FIG. 2 is an enlarged perspective view illustrating shock absorbers of the display apparatus of FIG. 1. FIG. 3 is a cross sectional view taken along a line A-B of FIG. 1.

Referring to FIGS. 1 to 3, the display apparatus includes a first substrate 100, a pixel area 140, a second substrate 120, a sealing members 160 and 170 and shock absorbers 180.

The display apparatus is an electronic device displaying some images. For example, the display apparatus is a flat display apparatus.

The first substrate 100 has a sealing area SA and a peripheral area PA surrounding the sealing area SA, and the pixel area 140 is disposed in the sealing area SA, and some wiring transferring signals and power to the pixel area 140 may be disposed in the sealing area SA.

The first substrate 100 may be an inorganic substrate including a glass or poly silicon, and may be a plastic substrate including a polyethylene terephthalate (PET), a polyethylennaphthalate (PEN), a polyimide, etc., and the first substrate 100 may be used as a flexible display substrate including a metal or a polymer having flexibility.

The pixel area 140 may include a liquid crystal device of a liquid crystal display (LCD), an organic light emitting diode of an organic light emitting display (OLED), an electrophoresis device of an electrophoresis display, etc. However, the pixel area 140 is not limited by the examples listed above. The pixel area may further include a switching device such as thin film transistor, in order to control the display device.

The second substrate 120 faces the first substrate 100. For example, the second substrate 120 may be disposed on a side substantially parallel to the first substrate 100. The second substrate 120 covers pixel elements of the pixel area 140. In the exemplary embodiment, the second substrate 120 may be disposed apart from the pixel area 140 by a predetermined distance as illustrated in FIG. 3. In another exemplary embodiment, the second substrate 120 may be disposed directly on the pixel area 140.

The second substrate 120 should have chemical stability and tight encapsulation in order to protect the pixel elements of the pixel area 140 on the first substrate 100, and the second substrate 120 should have sufficient transmittance for visible light in order to display a high definition image. Thus, the second substrate 120 may include a glass, a metal film, an organic or an in organic insulation material, etc.

The sealing member 160 and 170 forms a boundary of the sealing area SA and the peripheral area PA, and the sealing member 160 and 170 is disposed between the first substrate 100 and the second substrate 120. The sealing member 160 and 170 includes at least one or more sealants. In order to isolate the pixel elements of the pixel area 140 from external environment the sealing member 160 and 170 forms a closed loop when viewed at the top.

In the exemplary embodiment, the sealing member 160 and 170 may include two sealants. In another exemplary embodiment, the sealing member 160 and 170 may include three or more sealants. In still another exemplary embodiment, the sealing member 160 and 170 may include one sealant including a single material or a composite material.

In the exemplary embodiment, a first sealant 170 and a second sealant 160 may directly contact each other as illustrated in FIG. 1. In another exemplary embodiment, the first sealant 170 and the second sealant 160 may be disposed apart from each other by a predetermined distance. In still another exemplary embodiment, another sealant may be disposed between the first sealant 170 and the second sealant 160.

In the exemplary embodiment, one of sealants of the sealing member 160 and 170 may include an organic material, and another sealant may include an inorganic material. The inorganic sealant has high moisture-proof because pore space of inter molecules of the inorganic sealant are relatively small compared to the organic sealant. For example, the organic sealant 170 may be disposed at inside and the inorganic sealant 160 may be disposed at outside surrounding the organic sealant 170, in order to protect the organic sealant 170 from the external moisture. However, positions of sealants may be swapped with each other.

The first sealant 170 may include a resin compound such as an epoxy resin compound. For example, the first sealant 170 may include an ultra violet (UV) hardener such as a bisphenol-F, and may also include a bisphenol-A, an acryl, a phenyl silicone, etc. The organic sealant 170 having elastic characteristic may absorb the external impact, so that the organic sealant 170 may prevent the inorganic sealant 160 from breaking away from the first substrate 100 or the second substrate 120.

As the inorganic sealant, the second sealant 160 may include a glass material or a frit, and the second sealant 160 may include one of various inorganic materials. For example, when the sealing member 160 and 170 includes frit, the sealing member 160 and 170 may be formed by hardening process with low temperature, and the frit has high durability and moisture-proof by closed encapsulation. The frit may be hardened by a laser or infrared ray. For example, the frit may include a base material such as a silicon dioxide (SiO₂), a boron trioxide (B₂O₃), an aluminum oxide (Al₂O₃), etc. and an additive such as a copper oxide (CuO), an iron (III) oxide (Fe₂O₃), a titanium dioxide (TiO₂), etc.

In the exemplary embodiment, the shock absorbers 180 are arranged along a predetermined direction toward to peripheral area PA from a boundary of the sealing member 160 and 170. In FIG. 1, an arranging direction of the shock absorbers 180 is marked with an arrow CD.

In the exemplary embodiment, the shock absorbers 180 have concave bowl shape. For example, the shock absorbers 180 may have hemisphere shape as illustrated in FIG. 3. However the shape of the shock absorbers 180 is not limited by the example above. The shock absorbers 180 may have one of various shapes such as a cylinder, a cube, a tetrahedron, etc.

Generally, when a crack exists in some material, a stress is concentrated on the crack.

A maximum stress at an edge of the crack is determined by following formula,

$${σ}_{max} = σ ( 1 + 2 \frac{a}{b} ) = σ ( 1 + 2 \sqrt{\frac{a}{ρ}} )$$

wherein the crack has an elliptical shape, a 2a is a length of the crack, a 2b is a width of the crack, a ñ is a radius of curvature of the crack tip and a ó is a magnitude of the external stress. In addition, a stress concentration factor K is defined to a ratio for óₘₐₓ and ó, as follows,

$$K = \frac{{σ}_{max}}{σ} .$$

For example, the stress that is caused by external impact may be easily concentrated on corner regions of the closed loop. However, the display apparatus according to the exemplary embodiment may concentrate the stress on not the corner region of the closed loop but the shock absorbers 180 by using a principle that the stress is concentrated on around the crack, as mentioned above. In this embodiment, a shockwave caused by the external impact may be absorbed by the shock absorbers 180 which acts as a dummy crack, and is propagated toward to the arranging direction of the shock absorbers 180 and disappears. Thus, the shock absorbers 180 can prevent the sealing member 160 and 170 from a breaking by the stress.

In the exemplary embodiment, the shock absorbers 180 may have a circular shape when viewed at the top, as illustrated in FIGS. 1 and 2. The circular shape has smaller stress concentration factor than the factor of elliptical shape because the circular shape has a same length and width. Thus, the burden of the substrate including the shock absorbers 180 is reduced. In another exemplary embodiment, the shock absorbers 180 may also have elliptical shape when viewed at the top.

In the exemplary embodiment, the shock absorbers 180 may be arranged along a straight direction. For example, the shock absorbers 180 may be arranged along a normal direction of one side of the closed loop that is formed by the sealing member 160 and 170 from the side of the closed loop, as illustrated in FIG. 1. An arranging direction of the shock absorbers is marked with an arrow CD in FIGS. 1 and 2. In this embodiment, the shockwave is propagated toward to the arranging direction CD by the shock absorbers 180. In another exemplary embodiment, the shock absorbers 180 may be arranged along a spiral direction.

In the exemplary embodiment, the shock absorbers 180 may be arranged by one row. In another exemplary embodiment, the shock absorbers 180 may be arranged by two or more rows.

In the exemplary embodiment, the shock absorbers 180 may be disposed on the first substrate 100 as illustrated in FIG. 3. For example, when the first substrate 100 includes poly silicon and the sealing member 160 and 170 includes a frit, the first substrate 100 is relatively ductile compared to the frit and the first substrate 100 is relatively stronger to the stress compared to the frit, so that the first substrate 100 including the shock absorber 180 is suitable to absorb stress applied to the frit.

FIG. 4 is a cross sectional view illustrating a display apparatus according to another exemplary embodiment of the present invention.

In the exemplary embodiment, all elements of the display apparatus except for a plurality of shock absorbers 182 are substantially same as corresponding elements of the display apparatus of FIG. 1. Thus, a duplicated description of the corresponding elements will be omitted.

Referring to FIG. 4, the display apparatus includes a first substrate 100, a pixel area 140, a second substrate 120, a sealing member 160 and 170 and a plurality of shock absorbers 182.

In the exemplary embodiment, the shock absorbers 182 may be dummy cracks having concave bowl shapes in order to absorb the shockwave. The shock absorbers 182 may have one of various shapes such as a cylinder, a cube, a tetrahedron, etc. In addition, the shock absorbers 182 may be arranged along a predetermined direction in order to exhaust the absorbed shockwave to outside. Specifically, the shock absorbers 182 may be arranged along a direction toward to peripheral area PA from a side of the closed loop that is formed by the sealing member 160 and 170. The direction may be a straight direction or a spiral direction. The shock absorbers 182 may be arranged by one row, or the shock absorbers 182 may be arranged by two or more rows.

In the exemplary embodiment, the shock absorbers 182 may be disposed on the second substrate 120 as illustrated in FIG. 4.

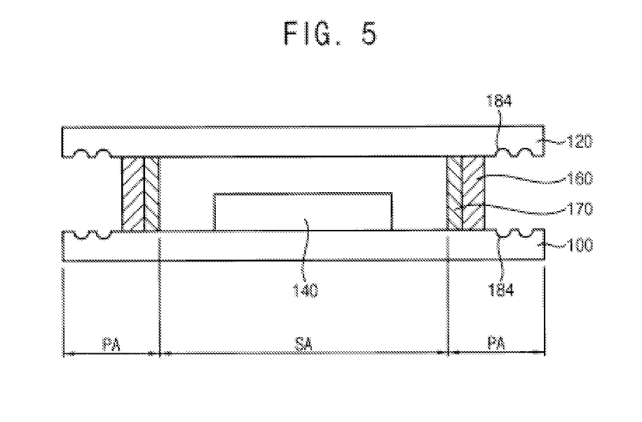

FIG. 5 is a cross sectional view illustrating a display apparatus according to another exemplary embodiment of the present invention.

In the exemplary embodiment, all elements of the display apparatus except for a plurality of shock absorbers 184 are substantially same as corresponding elements of the display apparatus of FIG. 1. Thus, a duplicated description of the corresponding elements will be omitted.

Referring to FIG. 5, the display apparatus includes a first substrate 100, a pixel area 140, a second substrate 120, a sealing member 160 and 170 and a plurality of shock absorbers 184.

In the exemplary embodiment, the shock absorbers 184 may be dummy cracks having concave bowl shapes in order to absorb the shockwave. The shock absorbers 184 may have one of various shapes such as a cylinder, a cube, a tetrahedron, etc. In addition, the shock absorbers 184 may be arranged along a predetermined direction in order to exhaust the absorbed shockwave to outside. Specifically, the shock absorbers 184 may be arranged along a direction toward to peripheral area PA from a side of the closed loop that is formed by the sealing member 160 and 170. The direction may be a straight direction or a spiral direction. The shock absorbers 184 may be arranged by one row, or the shock absorbers 184 may be arranged by two or more rows.

In the exemplary embodiment, the shock absorbers 184 may be disposed on the first substrate 100 and the second substrate 120 as illustrated in FIG. 5.

According to the exemplary embodiments, the shock absorbers 180, 182 and 184 can absorb the shockwave caused by the external impact, and can propagate the shockwave toward to the arranging direction of the shock absorbers 180, 182 and 184, so that the shock absorbers 180, 182 and 184 may relieve the stress applied to the sealing member 160 and 170. In particular, when the sealing member 160 and 170 includes the frit sealant delicate for stress, the shock absorbers 180, 182 and 184 may prevent the sealing member 160 and 170 from the breaking. Therefore, durability and productivity of the display apparatus are improved.

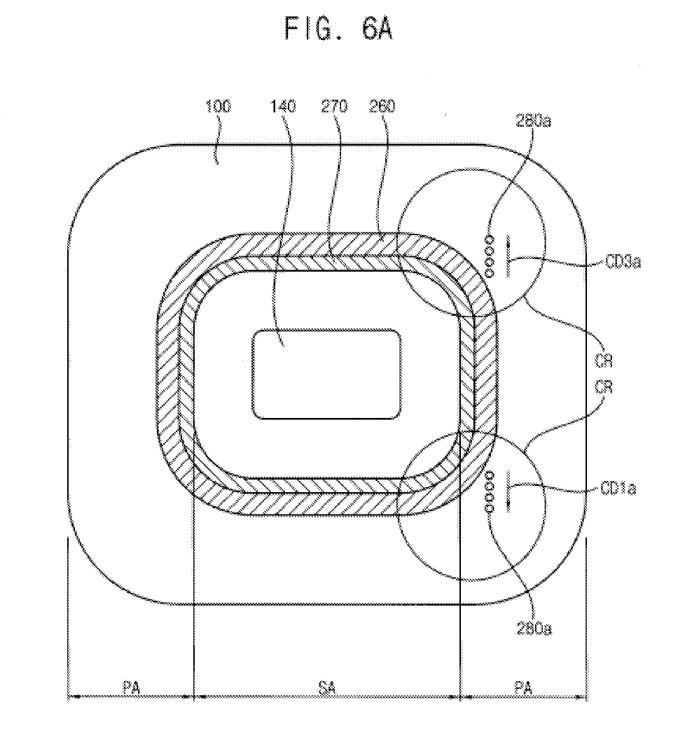

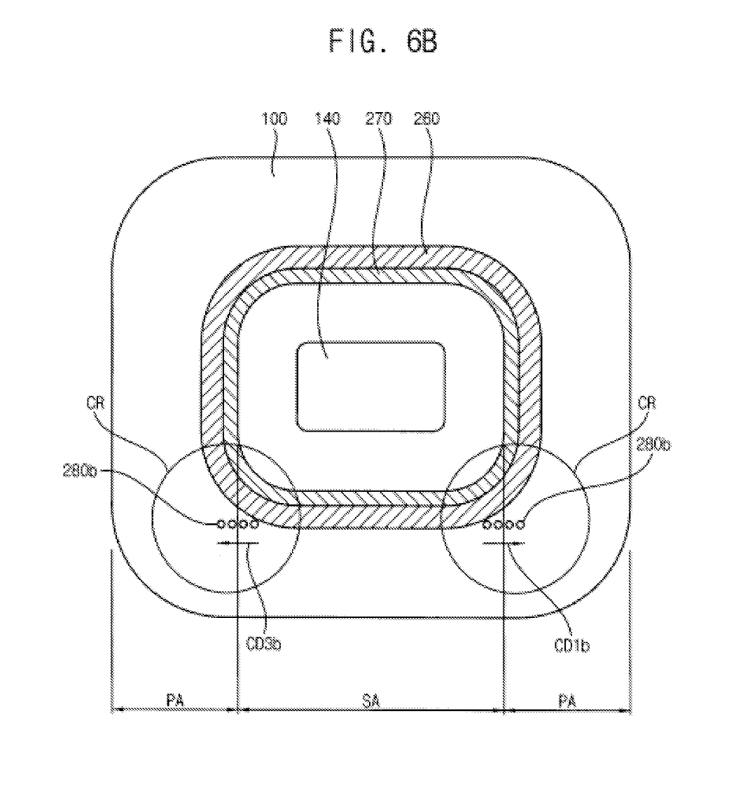

FIG. 6A is a planar view illustrating a display apparatus according to another exemplary embodiment of the present invention. FIG. 6B is a planar view illustrating a display apparatus according to another exemplary embodiment of the present invention.

In the exemplary embodiment, all elements of the display apparatus except for a sealing member 260 and 270 and a plurality of shock absorbers 280a and 280b are substantially same as corresponding elements of the display apparatus of FIG. 1. Thus, a duplicated description of the corresponding elements will be omitted.

Referring to FIGS. 6A and 6B, the display apparatus includes a first substrate 100, a pixel area 140, a second substrate 120, a sealing member 260 and 270 and a plurality of shock absorbers 280a and 280b.

The sealing member 260 and 270 forms a boundary of the sealing area SA and the peripheral area PA, and the sealing member 260 and 270 includes a plurality of sealants 260 and 270. The sealing member 260 and 270 is disposed between the first substrate 100 and the second substrate 120. In order to isolate the pixel elements of the pixel area 140 from external environment, the sealing member 260 and 270 forms a closed loop when viewed at the top. In the exemplary embodiment, the closed loop may have a rectangle shape with rounded corner. In another exemplary embodiment, the closed loop may have a polygon shape. In still another exemplary embodiment, the closed loop may have a circular shape or elliptical shape.

In the exemplary embodiment, a first sealant 270 and a second sealant 260 may directly contact each other as illustrated in FIGS. 6A and 6B. In another exemplary embodiment, the first sealant 270 and the second sealant 260 may be disposed apart from each other by a predetermined distance. In still another exemplary embodiment, another sealant may be disposed between the first sealant 270 and the second sealant 260. In still another exemplary embodiment, the sealing member 260 and 270 may be one sealant.

One sealant of the sealing member 260 and 270 may include an organic material, and another sealant may include an inorganic material. For example, the organic sealant 270 may be disposed at inside and the inorganic sealant 260 may be disposed at outside surrounding the organic sealant 270, in order to protect the organic sealant 270 from the external moisture. However, positions of sealants may be swapped with each other.

The first sealant 270 may include a resin compound such as an epoxy resin compound. A detailed description of the first sealant 270 is described above with referring to FIG. 1.

As the inorganic sealant, the second sealant 260 may include glass material or frit, and the second sealant 260 may also include one of various inorganic materials. A detailed description of the second sealant 260 is described above with referring to FIG. 1.

In the exemplary embodiment, the shock absorbers 280a and 280b may be dummy cracks having concave bowl shapes in order to absorb the shockwave. The shock absorbers 280a and 280b may have one of various shapes such as a cylinder, a cube, a tetrahedron, etc. In addition, the shock absorbers 280a and 280b may be arranged along a predetermined direction in order to exhaust the absorbed shockwave to outside. Specifically, the shock absorbers 280a and 280b may be arranged along a direction toward to peripheral area PA from a side of the closed loop that is formed by the sealing member 260 and 270. The direction may be a straight direction or a spiral direction. The shock absorbers 280a and 280b may be arranged by one row, or the shock absorbers 280a and 280b may be arranged by two or more rows.

The arranging direction CD1a, CD3a, CD1b and CD3b of the shock absorbers 280a and 280b may be tangent direction of a first side of the closed loop, arranging directions CD1a and CD1b are defined to a first direction, and a parallel directions substantially parallel to the first directions CD1a and CD1b are also defined to the first direction. For example, when the closed loop is a rectangle with rounded corners, the first side may be a short side of the rectangle, and the first direction CD1a may be a tangent direction of the short side of the rectangle as illustrated in FIG. 6A. For example, the first side may be a long side of the rectangle, and the first direction CD1b may be a tangent direction of the long side as illustrated in FIG. 6B.

In the exemplary embodiment, the shock absorbers 280a and 280b may be arranged along a first direction CD1a and CD1b and a third direction CD3a and CD3b that is opposite to the first direction CD1a and CD1b, toward to the peripheral area PA from both corner regions CR of the first side of the closed loop that is formed by the sealing member 260 and 270. For example, when the closed loop is a rectangle shape with rounded corners, the shock absorbers 280a may be arranged along the first direction CD1a and the third direction CD3a that is opposite to the first direction CD1a, toward to the peripheral area PA from both corner regions CR of the short side of the rectangle, as illustrated in FIG. 6A. For example, the shock absorbers 280b may be arranged along the first direction CD1b and the third direction CD3b that is opposite to the first direction CD1b, toward to the peripheral area PA from both corner regions CR of the long side of the rectangle, as illustrated in FIG. 6B.

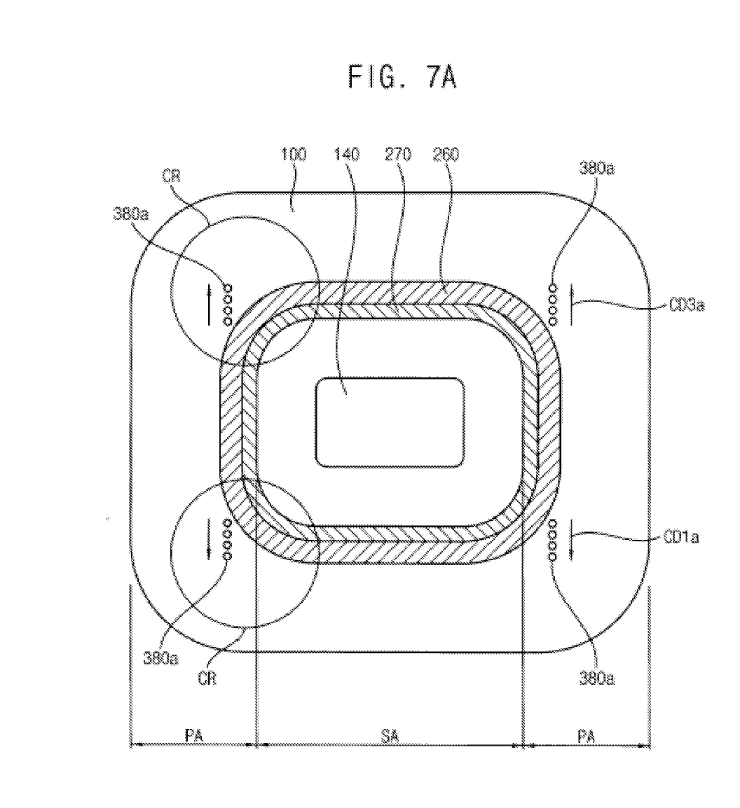

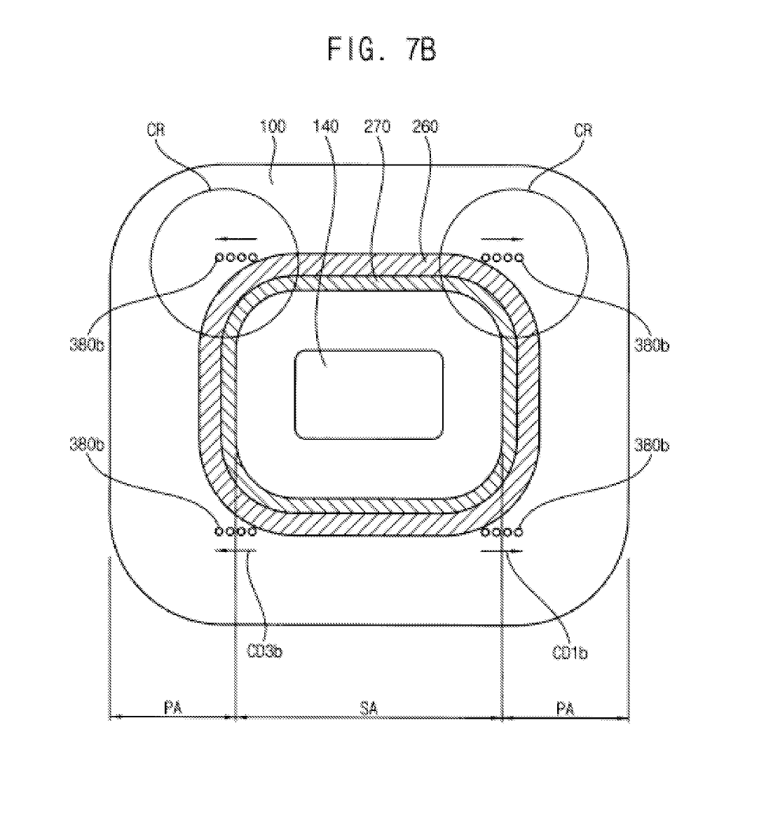

FIG. 7A is a planar view illustrating a display apparatus according to another exemplary embodiment of the present invention. FIG. 7B is a planar view illustrating a display apparatus according to another exemplary embodiment of the present invention.

In the exemplary embodiment, all elements of the display apparatus except for a plurality of shock absorbers 380a and 380b are substantially the same as corresponding elements of the display apparatus of FIGS. 6A and 6B. Thus, a duplicated description of the corresponding elements is omitted.

Referring to FIGS. 7A and 7B, the display apparatus includes a first substrate 100, a pixel area 140, a second substrate 120, a sealing member 260 and 270 and a plurality of shock absorbers 380a and 380b.

In the exemplary embodiment, the shock absorbers 380a and 380b may be dummy cracks having concave bowl shapes in order to absorb the shockwave. The shock absorbers 380a and 380b may have one of various shapes such as a cylinder, a cube, or a tetrahedron. In addition, the shock absorbers 380a and 380b may be arranged along a certain direction in order to exhaust the absorbed shockwave to the outside. Specifically, the shock absorbers 380a and 380b may be arranged along a direction toward to the peripheral area PA from a side of the closed loop formed by the sealing member 260 and 270. The direction may be a straight direction or a spiral direction. The shock absorbers 380a and 380b may be arranged by one row, or the shock absorbers 380a and 380b may be arranged by two or more rows.

The arranging directions CD1a, CD3a, CD1b and CD3b of the shock absorbers 380a and 380b may be a tangent direction of a first side of the closed loop, the arranging directions CD1a and CD1b are defined to a first direction, and parallel directions substantially parallel to the first directions CD1a and CD1b are also defined to the first direction. For example, when the closed loop are rectangle with rounded corner, the first side may be a short side of the rectangle, and the first direction CD1a may be a tangent direction of the short side as illustrated in FIG. 7A. For example, the first side may be a long side of the rectangle, and the first direction CD1b may be a tangent direction of the long side as illustrated in FIG. 7B.

In the exemplary embodiment, the shock absorbers 380a and 380b may be arranged along the first direction CD1a and CD1b and a third direction CD3a and CD3b that is opposite to the first direction CD1a and CD1b, toward to the peripheral area PA from both corner regions CR of the first side of the closed loop that is formed by the sealing member 260 and 270. In addition, the shock absorbers 380a and 380b may further be arranged along the first direction CD1a and CD1b and the third direction CD3a and CD3b, toward to the peripheral area PA from both corner regions CR of an opposite side substantially parallel to the first side. For example, when the closed loop is a rectangle shape with rounded corner, the shock absorbers 380a may be arranged along the first direction CD1a and the third direction CD3a that is opposite to the first direction CD1a, toward to the peripheral area PA from the four corner regions CR of short sides facing each other of the rectangle, as illustrated in FIG. 7A. For example, the shock absorbers 380b may be arranged along the first direction CD1b and the third direction CD3b that is opposite to the first direction CD1b, toward to the peripheral area PA from four corner regions CR of long sides facing each other of the rectangle, as illustrated in FIG. 7B.

According to exemplary embodiments, the shock absorbers 280a, 280b, 380a and 380b can absorb shockwaves caused by external impact and can propagate the shockwaves toward to the arranging direction CD1a, CD3a, CD1b and CD3b, so that the shock absorbers 280a, 280b, 380a and 380b may reduce the stress applied to the sealing member 260 and 270. In particular, the shock absorbers 280a, 280b, 380a and 380b may be arranged on the corner regions of the closed loop, so that the concentration of the stress at the corner regions of the closed loop is relived.

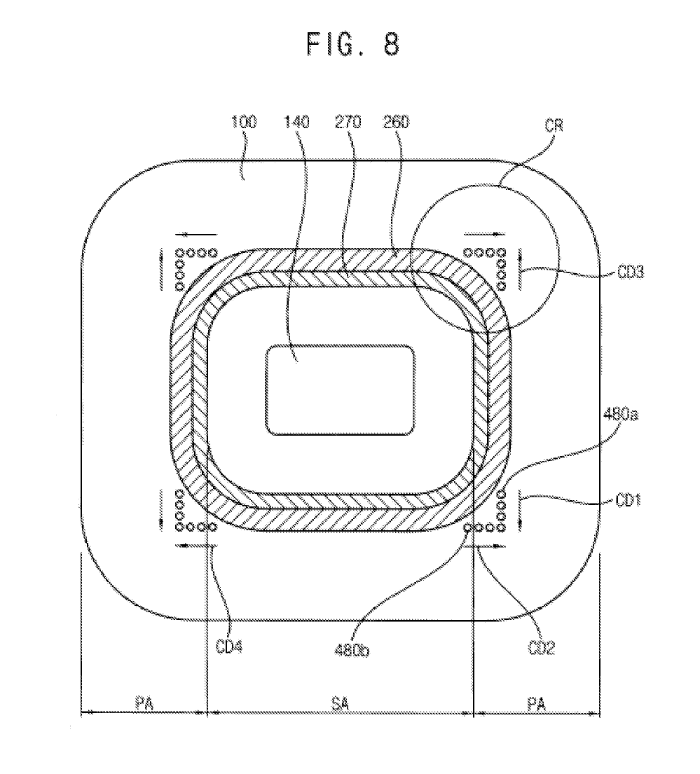

FIG. 8 is a planar view illustrating a display apparatus according to further still another exemplary embodiment of the present invention.

In the exemplary embodiment, all elements of the display apparatus except for a plurality of shock absorbers 480a and 480b are substantially the same as corresponding elements of the display apparatus of FIGS. 7A and 7B. Thus, a duplicated description of the corresponding elements will be omitted.

Referring to FIG. 8, the display apparatus includes a first substrate 100, a pixel area 140, a second substrate 120, a sealing member 260 and 270 and a plurality of shock absorbers 480a and 480b.

In the exemplary embodiment, the shock absorbers 480a and 480b may be dummy cracks having concave bowl shapes in order to absorb the shockwave. The shock absorbers 480a and 480b may have one of various shapes such as a cylinder, a cube, or a tetrahedron. In addition, the shock absorbers 480a and 480b may be arranged along a predetermined direction in order to exhaust the absorbed shockwave to the outside. Specifically, the shock absorbers 480a and 480b may be arranged along a direction toward to peripheral area PA from a side of the closed loop that is formed by the sealing member 260 and 270. The direction may be a straight direction or a spiral direction. The shock absorbers 480a and 480b may be arranged by one row, or the shock absorbers 480a and 480b may be arranged by two or more rows.

The arranging directions of the shock absorbers 480a and 480b are marked with arrows CD1, CD2, CD3 and CD4 in FIG. 8. The CD1 is a tangent direction of a first side that is one of the sides of the closed loop. The CD1 is defined to a first direction. The CD3 is an opposite direction of the first direction CD1. The CD3 is defined to a third direction. In addition, parallel directions substantially parallel to the first direction CD1 is also defined to the first direction and parallel directions substantially parallel to the third direction CD3 is also defined to the third direction. The CD2 is a tangent direction of a second side that is another side linked with the first side, and the CD2 is defined to the second direction. The CD4 is an opposite direction of the second direction CD2, and the CD4 is defined to the fourth direction. In addition, parallel directions substantially parallel to the second direction CD2 are also defined to the second direction, and parallel directions substantially parallel to the fourth direction CD4 are also defined to the fourth direction. The first direction CD1 and the second direction CD2 are different direction each other, the first direction CD1 and the second direction CD2 meet at one point. For example, when the closed loop is rectangle shape with rounded corner as illustrated in FIG. 8, the first direction CD1 may be a tangent direction of a short side of the rectangle, and the second direction CD2 may be a tangent direction of long side linked with the short side of the rectangle. The first direction CD1 and the second direction CD2 meet at the point near the corner of the rectangle.

In the exemplary embodiment, some shock absorbers 480a may be arranged along the first direction CD1 and the third direction CD3, toward to the peripheral area PA from both corner regions CR of the first side of the closed loop that is formed by the sealing members 260 and 270. In the same way, the shock absorbers 480a may further be arranged along the first direction CD1 and the third direction CD3, from both corner regions of an opposite side substantially parallel to the first side. The other shock absorbers 480b may be arranged along the second direction CD2 and the fourth direction CD4, toward to the peripheral area PA from both corner regions CR of the second side linked with the first side. In the same way, the other shock absorbers 480b may further be arranged along the second direction CD2 and the fourth direction CD4 from both corner regions CR of an opposite side substantially parallel to the second side. For example, when the closed loop is rectangle shape with rounded corner as illustrated in FIG. 8, some shock absorbers 480a may be arranged along the first direction CD1 and the third direction CD3 from the four corner regions CR of short side of the rectangle. In the same way the other shock absorbers 480b may be arranged along the second direction CD2 and the fourth direction CD4 from four corner regions CR of the long side of the rectangle. As a result, the shock absorbers 480a and 480b are arranged around every corner region CR of the rectangle.

According to the exemplary embodiment, some shock absorbers 480a to be arranged along the first direction CD1 and the other shock absorbers 480b to be arranged along the second direction CD2 may cover every corner of the closed loop that is formed by the sealing member 260 and 270, so that the shock absorber 480a and 480b can absorb the shockwave caused by external impact effectively, and can propagate the shockwave to the outside. Thus, the shock absorbers 480a and 480b can relieve the stress concentrated on the corner of the closed loop.

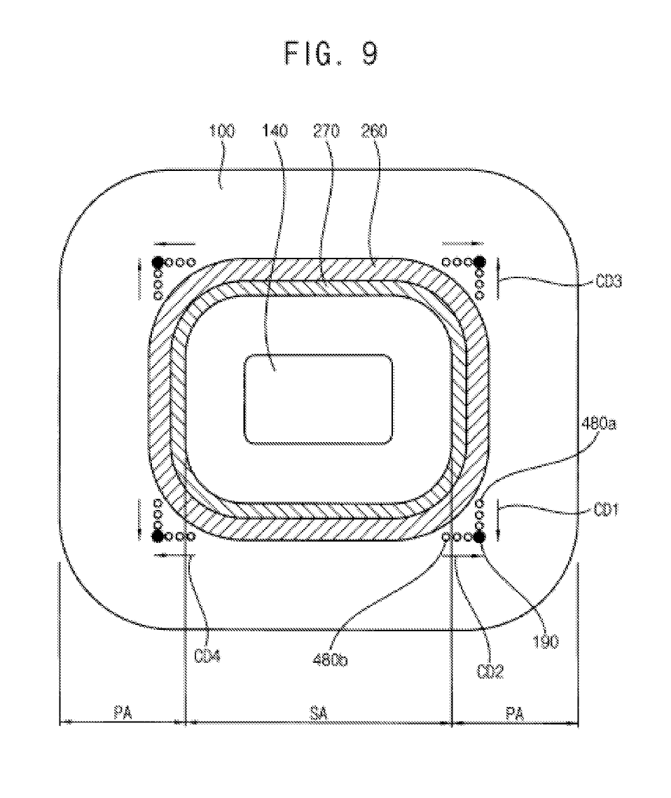

FIG. 9 is a planar view illustrating a display apparatus according to another exemplary embodiment of the present invention.

In the exemplary embodiment, all elements of the display apparatus except for a plurality of shock outlets 190 are substantially same as corresponding elements of the display apparatus of FIG. 8. Thus, a duplicated description of the corresponding elements will be omitted.

Referring to FIG. 9, the display apparatus includes a first substrate 100, a pixel area 140, a second substrate 120, a sealing member 260 and 270, a plurality of shock absorbers 480a and 480b and a shock outlet 190.

The shock outlet 190 exhausts the shockwave propagated along the first direction CD1 and the second direction CD2. The shock outlet 190 prevents the substrate including the shock absorbers 480a and 480b from the breaking caused by growth of the crack.

In the exemplary embodiment, the shock outlet 190 may be disposed where the shock absorbers 480a and 480b arranged in the first direction CD1 and the second direction CD2 intersect and the shock outlet 190 may also disposed where the shock absorbers 480a and 480b arranged in the third direction CD3 and the fourth direction CD4 intersect.

In the exemplary embodiment, the shock outlet 190 may include a hole or a void. For example, the shock outlet 190 may include a circular holes or voids as illustrated in FIG. 9. For example, the shock outlet 190 may include one of various shaped holes or voids such as polygonal shape, elliptical shape, etc. According to exemplary embodiment, the shockwave absorbed by shock absorber 480a and 480b is propagated to the first direction CD1 and the second direction CD2, and the shockwave may be exhausted by the hole or void of the shock outlet 190 that is disposed on the contact point of the first direction CD1 and the second direction CD2. In addition, when a new crack arises in the shock absorbers 480a and 480b, the shock outlet 190 can absorb the crack or can merge the crack in order to prevent a growth of the crack.

In the exemplary embodiment, the shock outlet 190 may be disposed on the first substrate 100. In this embodiment, the first substrate 100 is relatively ductile and stronger compared to the sealing member 260 and 270, so that the first substrate 100 is suitable to absorb and exhaust the stress. In another exemplary embodiment, the shock outlet 190 may disposed on the second substrate 120. In still another exemplary embodiment, the shock outlet 190 may disposed on both the first substrate 100 and the second substrate 120.

According to the exemplary embodiment, the shock absorbers 480a and 480b and the shock outlet 190 are arranged around every corner regions of the closed loop, so that the stress concentrated on the corner regions of the closed loop is relieved. In addition, the shock outlet 190 exhausts the shockwave to outside, so that the shock outlet 190 may prevent the substrate including the shock absorber 480a and 480b from the fracture caused by growth of the crack.

Therefore, the display apparatus of the present invention includes the shock absorber disposed around the corner regions of the closed loop, so that the sealing member may be protected from an external impact. In addition, the shock absorber and shock outlet may prevent the sealing member from breaking and damage caused by the impact during the manufacturing process. Thus, the productivity of the display apparatus will be improved.

Although it is described above that the present inventive concept is applied to the display apparatus, the present inventive concept may also be applied to an electronic device having sealing structure including a shock absorber and a shock outlet. For example, the present inventive concept may be applied to a display panel of television, a computer monitor, a laptop, a digital camera, a cellular phone, a smart phone, a smart pad, a personal digital assistant (PDA), a portable multimedia player (PMP), a MP3 player, a navigation system, a game console, a video phone, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A display apparatus, comprising:
a first substrate comprising a sealing area and a peripheral area outside the sealing area, the first substrate comprising a pixel area disposed in the sealing area;
a second substrate facing the first substrate;
a sealing member disposed at a boundary of the sealing area and the peripheral area, the sealing member forming a closed loop that encapsulates the pixel area; and
shock absorbers arranged adjacent to at least one side of the closed loop and in the peripheral area.

2. The display apparatus of claim 1, wherein:
the shock absorbers are arranged along a first direction and a third direction opposite to the first direction from both corner regions of a first side of the closed loop; and
the first direction being a tangent direction of the first side of the polygon.

3. The display apparatus of claim 2, wherein the shock absorbers are further arranged along the first direction and the third direction from both corner regions of an opposite side of the closed loop substantially parallel to the first side.

4. The display apparatus of claim 3, wherein:
the shock absorbers are further arranged along a second direction and a fourth direction opposite to the second direction from both corner regions of a second side of the closed loop connected to the first side, the second direction being a tangent direction of the second side; and
the shock absorbers are further arranged along the second direction and the fourth direction from both corner regions of an opposite side of the closed loop substantially parallel to the second side.

5. The display apparatus of claim 4, wherein the display apparatus further comprises at least one shock outlet disposed where the shock absorbers arranged in the first direction and the second direction intersect.

6. The display apparatus of claim 5, wherein the at least one shock outlet is disposed on the first substrate.

7. The display apparatus of claim 5, wherein the at least one shock outlet is disposed on the second substrate.

8. The display apparatus of claim 5, wherein the at least one shock outlet is disposed on the first substrate and at least one shock outlet is disposed on the second substrate.

9. The display apparatus of claim 1, wherein the shock absorbers are disposed on the first substrate.

10. The display apparatus of claim 1, wherein the shock absorbers are disposed on the second substrate.

11. The display apparatus of claim 1, wherein the shock absorbers are disposed on the first substrate and the second substrate.

12. The display apparatus of claim 5 wherein the at least one shock outlet comprises a void in the first substrate.
